(19) United States
(12) Patent Application Publication
(10) Pub. No.: US 2005/0181572 A1
(43) Pub. Date: Aug. 18, 2005

(54) Method for acoustically isolating an acoustic resonator from a substrate

(76) Inventors: Tracy Bell Verhoeven, San Jose, CA (US); Richard C. Ruby, Menlo Park, CA (US)

Correspondence Address: AGILENT TECHNOLOGIES, INC.;Intellectual Property Administration, Legal Department, DL429, P.O. Box 7599, Loveland, CO, 80537-0599, US

(21) Appl. No.: 10/778,618

(22) Filed: Feb. 13, 2004

(51) Int. Cl. H01L 21/20; H01L 21/46; H01L 21/30

(52) U.S. Cl. 438/379

(57) ABSTRACT

A method for acoustically isolating an acoustic resonator comprises: providing a substrate; forming a porous region in the substrate; forming the acoustic resonator on the porous region; and removing the porous region from the substrate. The removing forms a cavity that separates a portion of the acoustic resonator from the substrate. By using the techniques described herein, it is possible to form an acoustic resonator on a substrate and to form a cavity between the acoustic resonator and the substrate without depositing sacrificial material.

### RELATED ART

A film bulk acoustic resonator (FBAR) is typically composed of a layer of piezoelectric material, such as aluminum nitride, situated between two electrodes. When an alternating electrical potential is applied by the electrodes across the piezoelectric layer, the piezoelectric material expands and contracts, creating a vibration. Acoustic resonance of such vibration may be used to perform a desired function. In particular, devices fabricated from FBARs have been used in wireless communication devices, such as cellular telephones, for example, as frequency-shaping elements, including filters, duplexers, and resonators for oscillators.

Further, stacked FBARs, referred to as an SBAR, include multiple electrodes and piezoelectric layers. Each piezoelectric layer is situated between two electrodes such that an SBAR is essentially composed of multiple FBARs stacked on top of each other.

When an FBAR is formed on a surface of a substrate, energy from the FBAR's vibrations is absorbed by the substrate, reducing the FBAR's efficiency. To minimize the amount of energy absorbed by the substrate, it is desirable for an FBAR to be acoustically isolated from the substrate on which the FBAR is formed. Acoustic isolation can be obtained by suspending the FBAR over a cavity defined in the substrate. The cavity allows a substantial portion of the bottom surface of the FBAR to vibrate without contact with the substrate's surface. Acoustically isolating the FBAR from the substrate in such a manner increases the efficiency of the FBAR.

To fabricate a device having an acoustically isolated FBAR, a substrate is usually etched to form a cavity. Sacrificial material is then deposited on the substrate's surface to fill the cavity. The substrate's surface is then planarized to create a plane surface on which the FBAR is formed and to remove excess sacrificial material deposited on the substrate's surface outside the cavity. After planarization, the FBAR is formed on the sacrificial material, and the sacrificial material is then removed leaving the cavity beneath the FBAR.

Unfortunately, the planarization process is expensive to perform. Further, the process for etching the sacrificial material can involve an etchant incompatible with other components (e.g., circuits) formed on the substrate's surface. Care must be taken to ensure that the etching process used to remove the sacrificial material will not damage the components formed on the substrate's surface. For example, etchants have to be selected based on their compatibility with components residing on the substrate's surface. Alternatively, measures may be taken to isolate such components from potentially damaging etchants. However, such measures can significantly increase manufacturing costs.

### SUMMARY

Generally, embodiments of the present invention pertain to methods for acoustically isolating an acoustic resonator from a substrate.

A method in accordance with one exemplary embodiment of the present invention comprises: providing a substrate; forming a porous region in the substrate; forming an acoustic resonator on the porous region; and removing the porous region from the substrate. The removing forms a cavity that separates a portion of the acoustic resonator from the substrate.

A method in accordance with another exemplary embodiment of the present invention comprises: providing a silicon substrate; converting a portion of the silicon substrate into porous silicon; forming an acoustic resonator on the porous silicon; and removing the porous silicon from the substrate. The removing forms a cavity between the substrate and the acoustic resonator.

By using the techniques described herein, it is possible to form an acoustic resonator on a substrate and to form a cavity that isolates the acoustic resonator from the substrate without depositing sacrificial material. Therefore, an expensive planarization process is unnecessary to acoustically isolate the acoustic resonator from the substrate. In addition, processes used to remove the porous material from the cavity can be more compatible with components (e.g., circuit elements) formed on the substrate's surface compared to conventional processes that form the cavity by depositing sacrificial material and etching away the sacrificial material after the acoustic resonator has been formed.

### BRIEF DESCRIPTION OF THE DRAWINGS

The invention can be better understood with reference to the following drawings. The elements of the drawings are not necessarily to scale relative to each other, emphasis instead being placed upon clearly illustrating the present invention. Furthermore, like reference numerals designate corresponding parts throughout the several views.

FIG. 1 is a cross-sectional view illustrating a device manufactured in accordance with an exemplary embodiment of the present invention.

FIG. 2 is a top view of the device depicted in FIG. 1.

FIG. 3 is a flow chart illustrating an exemplary method that may be used to manufacture the device depicted in FIG. 1.

FIG. 4 is a cross-sectional view of a substrate after a masking layer has been formed on the substrate and patterned.

FIG. 5 is a top view of the substrate depicted in FIG. 4.

FIG. 6 is a cross-sectional view of the substrate depicted in FIG. 4 after a porous region has been formed in the substrate.

FIG. 7 is a top view of the device depicted in FIG. 6.

FIG. 8 is a cross-sectional view of the substrate depicted in FIG. 6 after the masking layer has been removed and a film bulk acoustic resonator (FBAR) has been formed on the substrate.

FIG. 9 is a cross-sectional view of an embodiment of the device of FIG. 1 in which the top electrode is reduced in area.

FIG. 10 is a top view of the device depicted in FIG. 9.

FIG. 11 is a cross-sectional view of a device manufactured in accordance with an exemplary embodiment of the present invention.

FIG. 12 is a top view of the device depicted in FIG. 9.

FIG. 13 is a flow chart illustrating an exemplary method for manufacturing the device depicted in FIG. 11.

FIG. 14 is a cross-sectional view of a substrate after a masking layer is formed on the substrate and patterned.

FIG. 15 is a top view of the substrate depicted in FIG. 14.

FIG. 16 is a cross-sectional view of the substrate depicted in FIG. 14 after porous regions have been formed in the substrate.

FIG. 17 is a cross-sectional view of the substrate depicted in FIG. 16 after masking and electrode layers have been removed from the substrate.

FIG. 18 is a cross-sectional view of the substrate depicted in FIG. 17 after an FBAR and a circuit element have been formed on the porous regions of the substrate.

### DETAILED DESCRIPTION

Embodiments of the present invention generally pertain to methods for acoustically isolating an acoustic resonator from a substrate on which the acoustic resonator is formed. In one exemplary embodiment of the present invention, the porosity of a portion of a substrate is increased to form a region of relatively high porosity, referred to hereafter as a “porous region,” compared to the remainder of the substrate. An acoustic resonator is then formed on the porous region. The porosity difference between the porous region and the remainder of the substrate enables the porous region to be etched away and, therefore, removed from the substrate without substantially removing or damaging the remainder of the substrate. Removing the porous region creates a cavity beneath the acoustic resonator that acoustically isolates the acoustic resonator from the substrate.

Since the cavity is formed without depositing sacrificial material, an expensive planarization process is unnecessary. The surface of the porous region that is later removed from the substrate to form the cavity is coplanar with the surface of the remainder of the substrate. This allows the acoustic resonator to be formed on the surface of the substrate and the porous region without the need to planarize the substrate's surface.

Ideally, processes used to remove the porous region are compatible with the components formed on the substrate's surface. However, if a desirable etchant for removing the porous region is unavailable, then the properties of the porous region may be changed to enable the porous region to be etched by different, more suitable etchants. For example, by oxidizing the porous region, it is possible to change the types of etchant that can be used to remove the porous region. Therefore, oxidization of the porous region may enable selection of a suitable etchant that is more compatible with components (e.g., circuitry) formed on the substrate's surface.

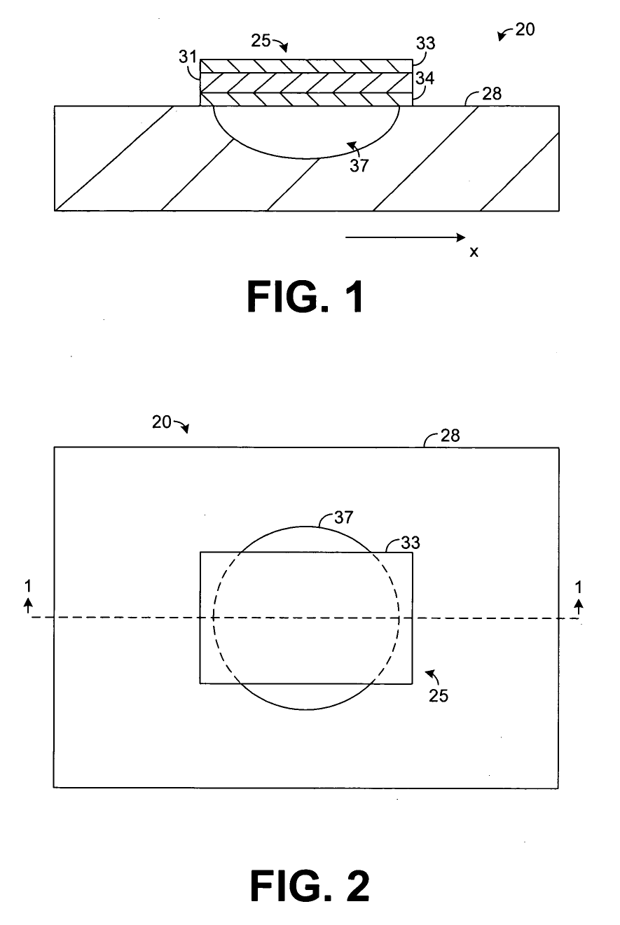

FIG. 1 depicts a device 20 manufactured in accordance with an exemplary embodiment of the present invention. The device 20 is composed of a film bulk acoustic resonator (FBAR) 25 formed on a substrate 28. In one embodiment, the substrate 28 is composed of silicon (Si), and the FBAR 25 has a piezoelectric layer 31 situated between two electrode layers 33 and 34. An air-filled cavity 37 in the substrate 28 is located below the FBAR 25 and acoustically isolates the FBAR 25 from the substrate 28. As shown in FIGS. 1 and 2, a peripheral region of the FBAR 25 resides on and is supported by the substrate 28. A substantial portion of the FBAR 25 is suspended over the cavity 37 and, therefore, does not contact or press against the substrate 28 as the FBAR 25 vibrates. Thus, the amount of acoustic energy that is dissipated into the substrate 28 is reduced compared to an FBAR that resides on a substrate without a cavity between the FBAR and the substrate.

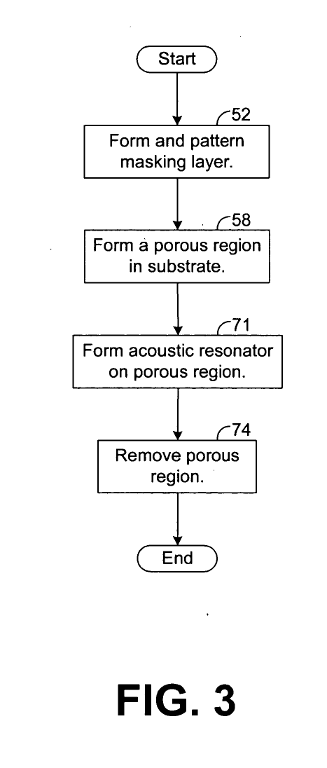

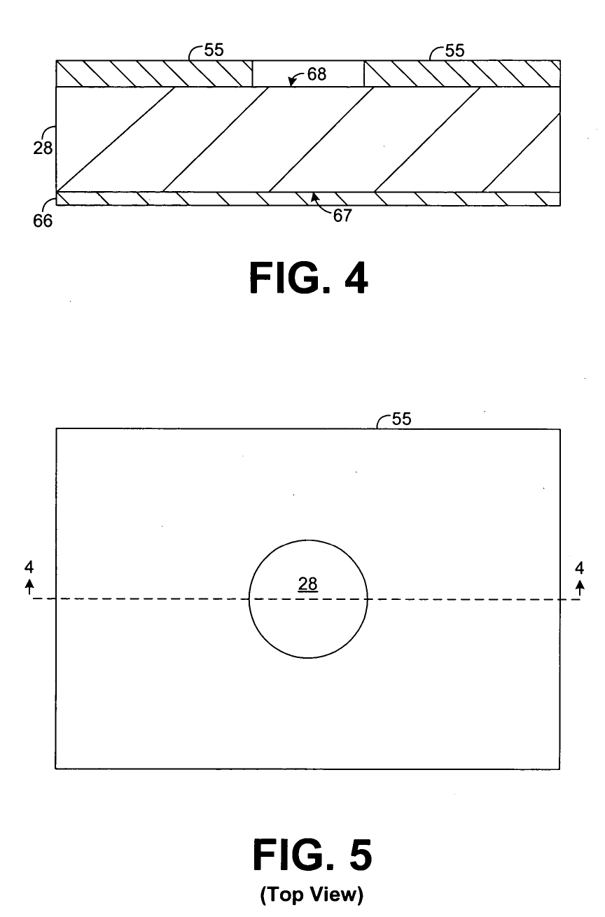

FIG. 3 depicts an exemplary method that may be used to manufacture the device 20 shown in FIG. 1. As shown in FIG. 4 and block 52 of FIG. 3, a masking layer 55 is deposited on the substrate 28 and is then patterned. In one embodiment in which the substrate is composed of silicon, the masking layer 55 is composed of silicon nitride, although other materials for the masking layer 55 are possible in other embodiments.

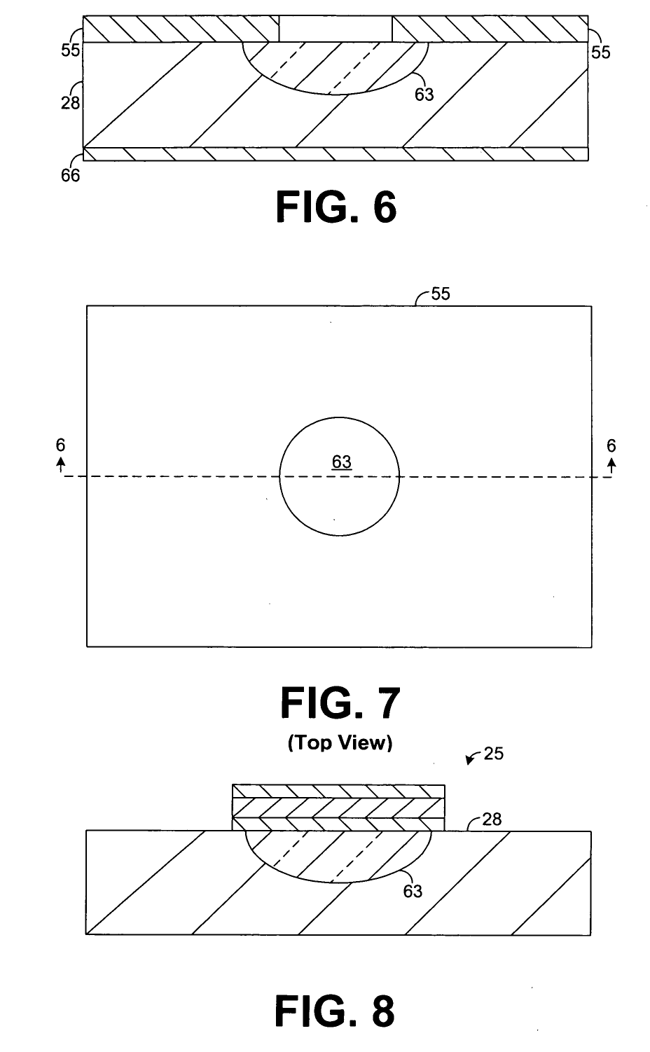

Referring to FIG. 5, the masking layer 55 is patterned to expose an area of the substrate's surface where the cavity 37 (FIG. 1) is to be formed. As shown in FIGS. 6 and 7, as well as block 58 of FIG. 3, a porous region 63 is formed in the substrate. In particular, the porosity of the region where the cavity 37 (FIG. 1) is to be formed is increased. In one exemplary embodiment, the substrate 28 is composed of silicon (Si), and a region 63 of porous, silicon is formed in the substrate 28.

For example, in one embodiment, the porous region 63 is formed by etching the substrate 28 shown in FIG. 5 with hydrofluoric acid (HF) while the substrate is subjected to an electrical bias. To provide a bias during etching, an electrode 66 is formed on the surface 67 of the substrate 28 remote from the surface 68 on which masking layer 55 is located, as shown in FIGS. 4 and 6. The substrate 28 is submerged in HF during etching, and a voltage difference is applied between the substrate 28 and the HF. The voltage difference is applied between the electrode 66 and another electrode (not shown) positioned in the HF. When the voltage difference provides a current density of approximately 10 to 100 milli-Amperes/centimeter² (mA/cm²) across the portion of the surface 68 of the substrate 28 exposed by the masking layer 55, the silicon exposed to the HF is converted into porous silicon, and the region 63 of porous silicon is formed in the substrate 28. After formation of the porous region 63, the electrode 66 may be removed from the substrate 28.

The surface of the porous region 63 formed as just described is flush with the top surface of the substrate 28. Therefore, it is not necessary for the substrate 28 to be planarized after formation of the porous region 63 and prior to formation of the FBAR 25.

After forming porous region 63, the masking layer 55 is removed. An embodiment of masking layer 55 composed of silicon nitride is etched away using phosphoric acid, although other types of etchant may be used in other embodiments to remove the masking layer 55.

Further, as shown in FIG. 8 and block 71 of FIG. 3, the FBAR 25 is formed on the porous region 63 using any suitable microfabrication technique, such as deposition, photolithography and etching. Suitable processes for fabricating an FBAR are known in the art. Then, as shown in FIG. 1 and block 74 of FIG. 3, the porous region 63 is removed using any suitable microfabrication technique, such as etching. In an embodiment in which the substrate 28 is composed of silicon and the region 63 is, therefore, composed of porous silicon, the region 63 is etched away by immersing the substrate 28 in dilute potassium-hydroxide (KOH), e.g., 10% KOH, at room temperature. Such an etching process takes only a few seconds to remove the porous silicon region 63 and is compatible with the materials of the FBAR 25 and those of many other types of components (e.g., circuit elements) that may also be formed on the substrate's surface.

The relatively high porosity of the porous region 63, compared to the remainder of the substrate 28, enables the region 63 to be etched away in a short time before the etching process significantly etches away or damages portions of the substrate 28 outside of region 63 or damages the FBAR. The removal of the porous region 63 from the substrate 28 forms cavity 37 (FIG. 1). Therefore, performing block 74 of FIG. 3 acoustically isolates the FBAR 25 from the substrate 28.

To determine the type of etching and the etchant used to remove the porous region 63, the porous region 63 may be oxidized. For example, between blocks 58 and 71 of FIG. 3, the substrate 28 may be oxidized using thermal oxidation by exposing the substrate 28 to hydrogen and oxygen at high temperature. When the substrate 28 is composed of silicon and the region 63 is, therefore, composed of porous silicon, oxidation of the porous silicon region 63 enables the region 63 to be etched away using HF, which is compatible with many types of components that may be formed on the substrate 28, including the FBAR 25. Thus, by oxidizing the porous region 63, HF may be used to remove the porous region 63 without damaging the FBAR 25 and other HF-resistant devices that may be formed on the substrate 28.

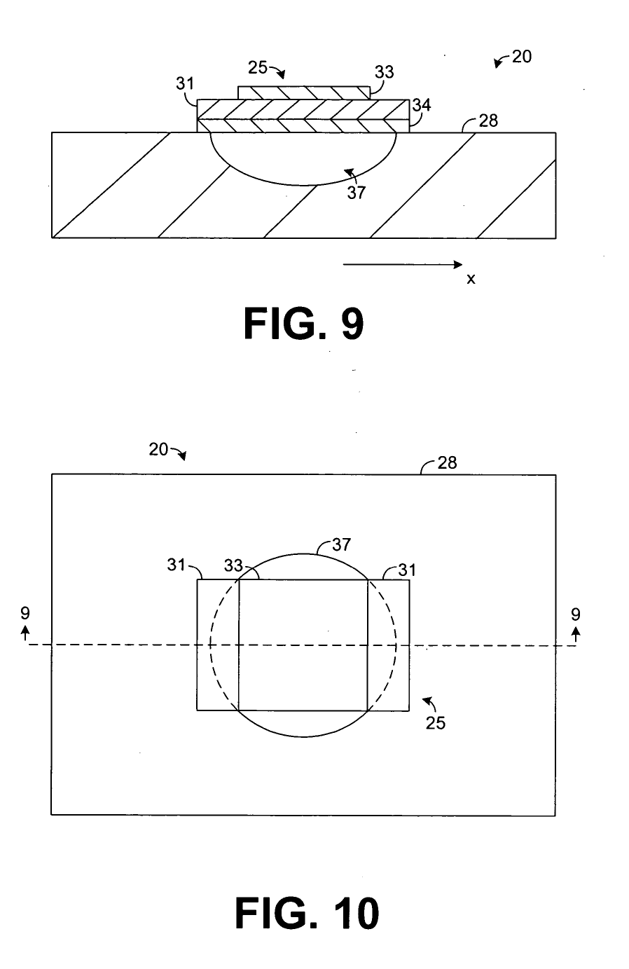

Referring to FIG. 1, the bottom electrode layer 34 residing on the surface of the substrate 28 supports the piezoelectric layer 31 and the top electrode layer 33. It is possible for the area of either or both of the piezoelectric layer 31 and the top electrode layer 33 to be less than the area of the bottom electrode layer 34. FIGS. 9 and 10 depict an exemplary embodiment in which the area of the top electrode layer 33 is less than that of the electrode layer 33 of FIG. 1. In this embodiment, a greater percentage of the top electrode layer 33 is positioned directly over the cavity 37.

Reducing the width of the top electrode layer 33 such that a greater percentage of the top electrode layer 33 is positioned directly over the cavity 37 increases the efficiency of the FBAR 25. Energy generated by the portion of the piezoelectric material positioned directly over the cavity 37 (i.e., the portion of the piezoelectric material within the periphery of the cavity 37) is not as easily dissipated into the substrate 28 compared to energy generated by the portion of the piezoelectric material positioned directly over the surface of the substrate 28 on which the bottom electrode 34 resides (i.e., the portion of the piezoelectric material outside the periphery of the cavity 37). Therefore, by reducing the area of the top electrode layer 33 positioned outside the periphery of the cavity 37, less energy is dissipated into the substrate 28.

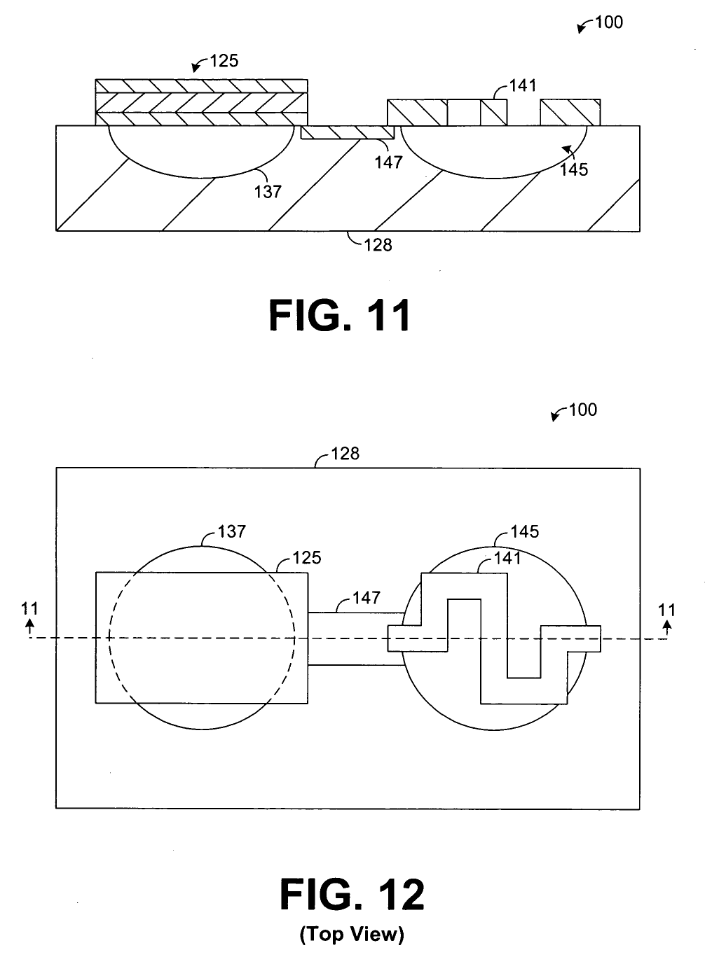

A method similar to that described above with reference to FIG. 3 can be used to electrically or thermally isolate other components (e.g., circuitry) formed on the surface of the substrate 28. For example, FIGS. 11 and 12 depict a device 100 having an FBAR 125 formed over a cavity 137 within a substrate 128, similar to the device 20 shown by FIG. 1. The device 100 also has a circuit element 141 suspended over a cavity 145. The cavity 145 electrically and thermally isolates the circuit element 141 from the substrate 128. In the exemplary embodiment depicted by FIG. 11, the circuit element 141 is an inductor that is electrically coupled to the FBAR 125 by a conductive trace 147 formed in the substrate 128. In other embodiments, other types of circuit element, such as capacitors, antennas, or switches, may be additionally or alternatively formed over the cavity 145 and coupled to the FBAR 125. However, in yet other embodiments, the circuit element 141 is suspended over the air gap 145, but is not electrically coupled to the FBAR 125.

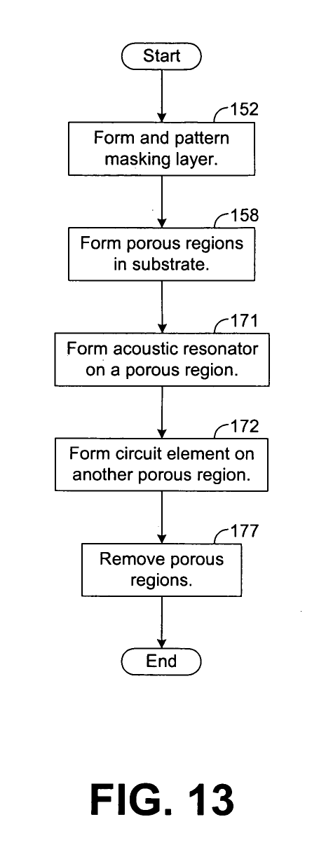

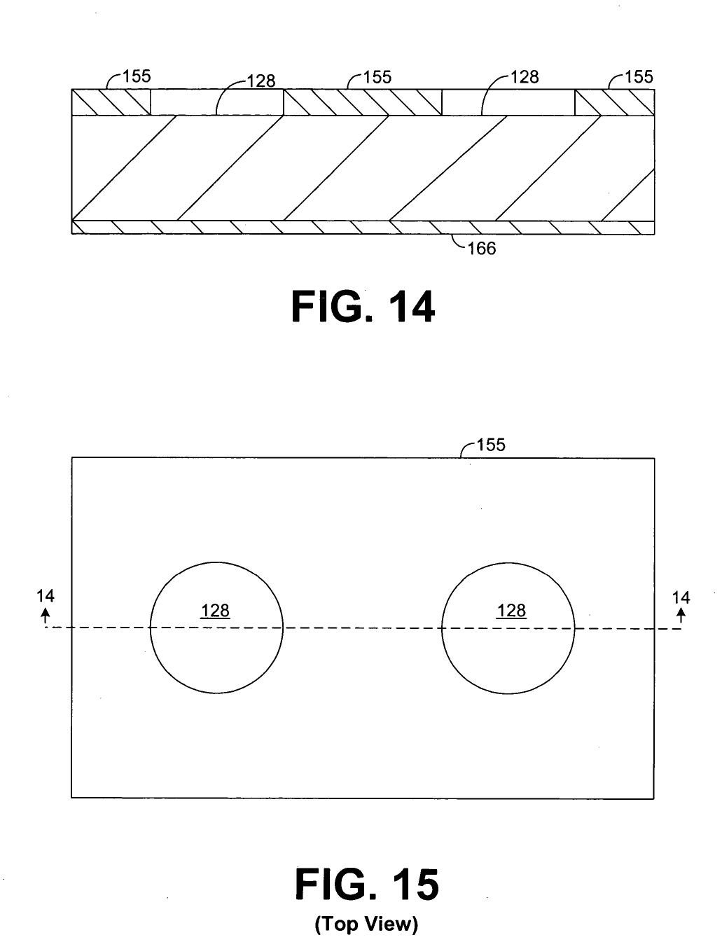

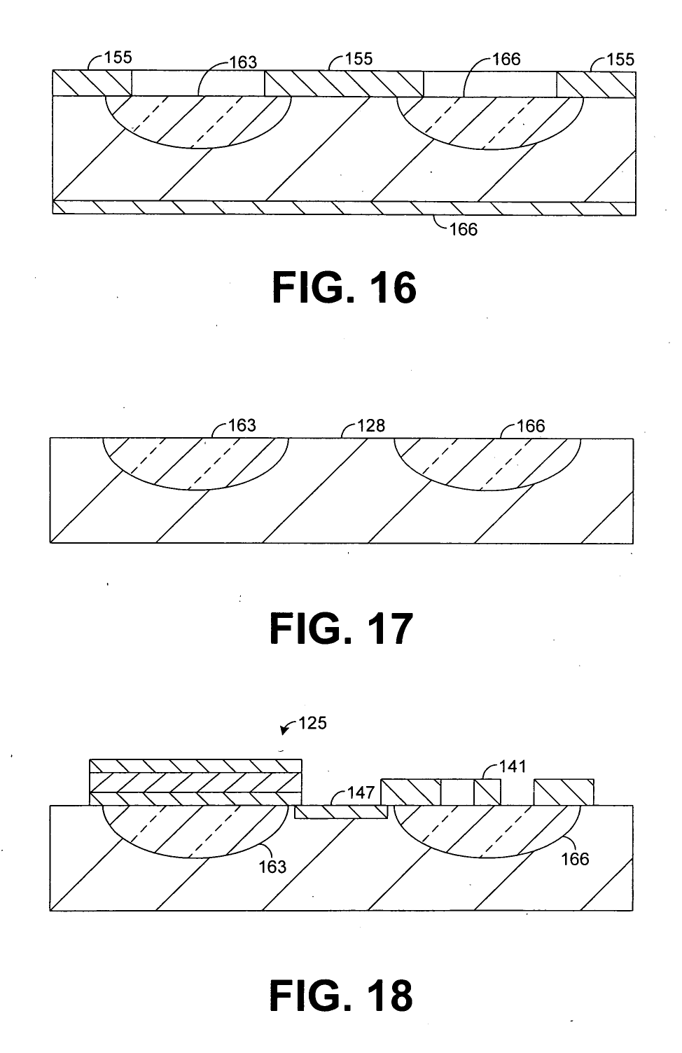

To reduce manufacturing expenses, it is possible to form both the cavity 137 and the cavity 145 at the same time using the same microfabrication process. FIG. 13 depicts an exemplary method that may be used to fabricate the device 100 of FIGS. 11 and 12. As shown in FIGS. 14 and 15, as well as block 152 of FIG. 13, a masking layer 155 is deposited on the substrate 128 and patterned. As shown in FIG. 16 and block 158 of FIG. 13, porous regions 163 and 166 are formed in the substrate 128. In an embodiment in which the substrate 128 is composed of silicon (Si), the porous regions 163 and 166 may be formed by etching the substrate 128 with hydrofluoric acid (HF) while the substrate is subject to an electrical bias, as described above. Such an etching process converts the silicon in regions 163 and 166 into porous silicon.

After forming porous regions 163 and 166 in the substrate 128, the masking layer and electrode layer 166 may be removed from the substrate 128, as shown in FIG. 17. Further, the FBAR 125 is formed on the porous region 163, as shown in FIG. 18 and block 171 of FIG. 13, and the circuit element 141 is formed on the porous region 166, as shown in FIG. 18 and block 172 of FIG. 13. The porous regions 163 and 166 are then etched away to form air gaps 137 and 145, respectively, as shown in FIG. 11 and block 177 of FIG. 13. The exemplary techniques described above for removing the porous region 63 (FIG. 8) may be used to remove the porous regions 163 and 166 shown in FIG. 15.

1. A method for acoustically isolating an acoustic resonator, the method comprising:
providing a substrate;
forming a porous region in said substrate;
forming the acoustic resonator on said porous region; and
removing said porous region from said substrate.

2. The method of claim 1, wherein said substrate comprises silicon and said porous region comprises porous silicon.

3. The method of claim 1, wherein said forming said porous region comprises etching said substrate while subjecting said substrate to an electrical bias.

4. The method of claim 1, further comprising oxidizing said porous region.

5. The method of claim 4, wherein said removing comprises etching said oxidized porous region with an etchant substantially incapable of etching said porous region.

6. The method of claim 1, wherein:
said porous region is a first porous region;
said forming said porous region additionally forms a second porous region in said substrate;
said removing additionally removes said second porous region; and
said method additionally comprises forming a circuit element on said second porous region.

7. The method of claim 6, wherein said circuit element is an inductor.

8. The method of claim 6, additionally comprising electrically coupling said circuit element to said acoustic resonator.

9. The method of claim 8, wherein said circuit element is an inductor.

10. The method of claim 6, further comprising oxidizing said porous regions.

11. A method for acoustically isolating an acoustic resonator, the method comprising:
providing a silicon substrate;
converting a portion of said silicon substrate into porous silicon;
forming said acoustic resonator on said porous silicon; and removing said porous silicon from said silicon substrate.

12. The method of claim 11, wherein said converting comprises etching said substrate while subjecting said substrate to an electrical bias.

13. The method of claim 11, further comprising oxidizing said porous silicon.

14. The method of claim 13, wherein:
said substrate and said acoustic resonator comprise etchable materials; and
said removing comprises etching said oxidized porous silicon with an etchant that etches said oxidized porous silicon in preference to said etchable materials.

15. The method of claim 11, wherein:
said portion is a first portion of said silicon substrate;
said converting additionally converts a second portion of said silicon substrate into porous silicon;
said removing additionally removes said porous silicon of said second portion; and
said method additionally comprises forming a circuit element on said porous silicon of said second portion.

16. The method of claim 15, wherein said circuit element is an inductor.

17. The method of claim 15, additionally comprising electrically coupling said circuit element to said acoustic resonator.

18. The method of claim 15, wherein said circuit element is an inductor.

19. The method of claim 15, wherein:
said substrate, said acoustic resonator and said circuit element comprise etchable materials; and
said removing comprises etching said oxidized porous silicon with an etchant that etches said oxidized porous silicon in preference to said etchable materials.
